(19) United States
(12) Patent Application Publication
(10) Pub. No.: US 2007/0184607 A1
(43) Pub. Date: Aug. 9, 2007

(54) Methods of forming integrated circuitry, and methods of forming dynamic random access memory cells

(76) Inventors: Eric R. Blomiley, Boise, ID (US); Joel A. Drewes, Boise, ID (US); D.V. Nirmal Ramaswamy, Boise, ID (US)

Correspondence Address: WELLS ST. JOHN P.S., 601 W. FIRST AVENUE, SUITE 1300, SPOKANE, WA, 99201, US

(21) Appl. No.: 11/724,789

(22) Filed: Mar. 15, 2007

Related U.S. Application Data
(62) Division of application No. 11/185,184, filed on Jul. 19, 2005.

(51) Int. Cl. H01L 21/8238

(52) U.S. Cl. 438/221

(57) ABSTRACT

The invention includes semiconductor processing methods in which openings are formed to extend into a semiconductor substrate, and the substrate is then annealed around the openings to form cavities. The substrate is etched to expose the cavities, and the cavities are substantially filled with insulative material. The semiconductor substrate having the filled cavities therein can be utilized as a semiconductor-on-insulator-type structure, and transistor devices can be formed to be supported by the semiconductor material and to be over the cavities. In some aspects, the transistor devices have channel regions over the filled cavities, and in other aspects the transistor devices have source/drain regions over the filled cavities. The transistor devices can be incorporated into dynamic random access memory, and can be utilized in electronic systems.

### TECHNICAL FIELD

The invention pertains to integrated circuitry, dynamic random access memory (DRAM), electronic systems, and semiconductor processing methods.

### BACKGROUND OF THE INVENTION

Semiconductor-on-insulator (SOI) constructions (for instance, silicon-on-insulator constructions) are frequently utilized for fabrication of integrated circuitry. For instance, it is common to utilize silicon-on-insulator constructions as substrates for integrated memory arrays, such as, for example, dynamic random access memory (DRAM) arrays.

SOI structures can provide numerous advantages compared to other structures utilized for fabrication of integrated circuitry. However, there can also be problems associated with SOI structures. For instance, there can be so-called floating body effects occurring between the semiconductor material of an SOI structure and the insulating material of the SOI structure (which is commonly a buried silicon dioxide, or other oxide). Also, if transistors are formed over an SOI substrate, there can be short-channel effects and junction leakage.

It is desirable to develop new structures having SOI-type properties so that advantages associated with SOI are manifested by the structures, and yet being different enough from conventional SOI so that at least some of the problems associated with conventional SOI can be alleviated, or preferably even prevented.

### SUMMARY OF THE INVENTION

In one aspect, the invention includes a semiconductor processing method. A semiconductor substrate is provided, and openings are formed to extend into the substrate. The substrate is annealed around the openings to form cavities within the substrate. The substrate is etched to expose the cavities, and the cavities are substantially filled with material. In particular aspects, the material utilized to substantially fill the cavities is insulative material, such as, for example, silicon dioxide, high-k material, and/or polymeric compositions.

In one aspect, the invention includes a method of forming an isolation region. A semiconductor substrate is provided, and openings are formed to extend into the substrate. The substrate is annealed around the openings to form cavities within the substrate. The substrate is etched to form trenches and expose the cavities. The cavities are substantially filled with a first electrically insulative material, and a second electrically insulative material is formed within the trenches. The second insulative material can be compositionally the same as the first insulative material or different.

In one aspect, the invention includes integrated circuitry. The circuitry comprises a semiconductor material, and segments of electrically insulative material within the semiconductor material. The segments are spaced from one another by intervening regions of the semiconductor material. A transistor is supported by the semiconductor material. The transistor comprises a transistor gate over the semiconductor material, and comprises a pair of source/drain regions proximate the gate. The transistor further comprises a channel region beneath the gate and between the source/drain regions. The channel region is primarily directly over a segment of the electrically insulative material and/or the source/drain regions are primarily over one or more segments of the electrically insulative material.

In one aspect, the invention includes a dynamic random access memory cell. Such memory cell comprises a semiconductor material, and segments of electrically insulative material within the semiconductor material. The segments are spaced from one another by intervening regions of the semiconductor material. A transistor is supported by the semiconductor material. The transistor comprises a transistor gate over the semiconductor material, and comprises a pair of source/drain regions proximate the gate. The transistor further comprises a channel region beneath the gate and between the source/drain regions. The source/drain regions are primarily directly over a pair of segments of the electrically insulative material, and the channel region is associated with an intervening region of the semiconductor material between the pair of segments of the electrically insulative material. A capacitor is electrically coupled with one of the source/drain regions.

In one aspect, the invention includes an electronic system. Such system comprises a processor in data communication with a memory device. At least one of the processor and the memory device includes integrated circuitry which comprises a semiconductor material, and segments of electrically insulative material within the semiconductor material. The segments are spaced from one another by intervening regions of the semiconductor material. The at least one of the processor and the memory device further includes a transistor supported by the semiconductor material. The transistor comprises a transistor gate over the semiconductor material, and comprises a pair of source/drain regions proximate the gate. The transistor further comprises a channel region beneath the gate and between the source/drain regions. In some applications one or both of the source/drain regions is primarily directly over one or more segments of the electrically insulative material, and in some applications the channel region is directly over a segment of the electrically insulative material.

### BRIEF DESCRIPTION OF THE DRAWINGS

Preferred embodiments of the invention are described below with reference to the following accompanying drawings.

FIG. 1 is a diagrammatic, cross-sectional view of a semiconductor wafer fragment at a preliminary processing stage of an exemplary aspect of the present invention.

FIG. 2 is a view of the FIG. 1 fragment shown at a processing stage subsequent to that of FIG. 1.

FIG. 3 is a view of the FIG. 1 fragment shown at a processing stage subsequent to that of FIG. 2.

FIG. 4 is a view of the FIG. 1 fragment shown at a processing stage subsequent to that of FIG. 3.

FIG. 5 is a view of the FIG. 1 fragment shown at a processing stage subsequent to that of FIG. 4.

FIG. 6 is a view of the FIG. 1 fragment shown at a processing stage subsequent to that of FIG. 5.

FIG. 7 is a view of the FIG. 1 fragment shown at a processing stage subsequent to that of FIG. 6.

FIG. 8 is a diagrammatic, cross-sectional view of a semiconductor wafer fragment shown at a processing stage comparable to that of FIG. 6 in accordance with another aspect of the present invention.

FIG. 9 is a diagrammatic view of a computer illustrating an exemplary application of the present invention.

FIG. 10 is a block diagram showing particular features of the motherboard of the FIG. 9 computer.

FIG. 11 is a high-level block diagram of an electronic system according to an exemplary aspect of the present invention.

FIG. 12 is a simplified block diagram of an exemplary memory device according to an aspect of the present invention.

### DETAILED DESCRIPTION OF THE PREFERRED EMBODIMENTS

This disclosure of the invention is submitted in furtherance of the constitutional purposes of the U.S. Patent Laws “to promote the progress of science and useful arts” (Article 1, Section 8).

The invention pertains to SOI-type structures in which the insulating material of the SOI is segmented, rather than being continuous. Accordingly, semiconductor material above the insulator of the SOI connects with semiconductor material below the SOI at locations between segments of the insulating material.

In particular aspects of the invention, integrated circuitry is formed to be supported by the SOI-type constructions. For instance, transistor devices can be formed to be supported by the SOI-type constructions. Such transistor devices can be considered to be partially-insulated in that the transistor devices can have portions over segments of insulative material and other portions which are not over segments of the insulative material.

Utilization of the SOI-type constructions having segmented insulative material, rather than continuous insulative material, can provide numerous advantages. For instance, partially-insulated transistors associated with the SOI-type constructions of the present invention can have reduced junction leakage and reduced short channel effects as compared to transistors associated with conventional SOI constructions. Also, utilization of the segmented insulating material in the SOI-type constructions of the present invention can avoid floating body effects associated with conventional SOI constructions.

Some efforts have previously been made to form partially-insulated transistors by utilizing selective epitaxial deposition of Si/SiGe/Si layers with a selective etch to remove SiGe. However, such flow typically has problems due to: (1) difficulties in controlling the SiGe/Si deposition, (2) crystallographic defects caused by Si on SiGe, and (3) difficulties in precisely controlling the selective etch. Methodology of the present invention can provide easier processing compared to Si/SiGe/Si epitaxial structures formed with selective SiGe etches, and the Si material utilized in SOI-type constructions of the present invention can be relatively defect free which is difficult to achieve utilizing selective epitaxial growth on oxides.

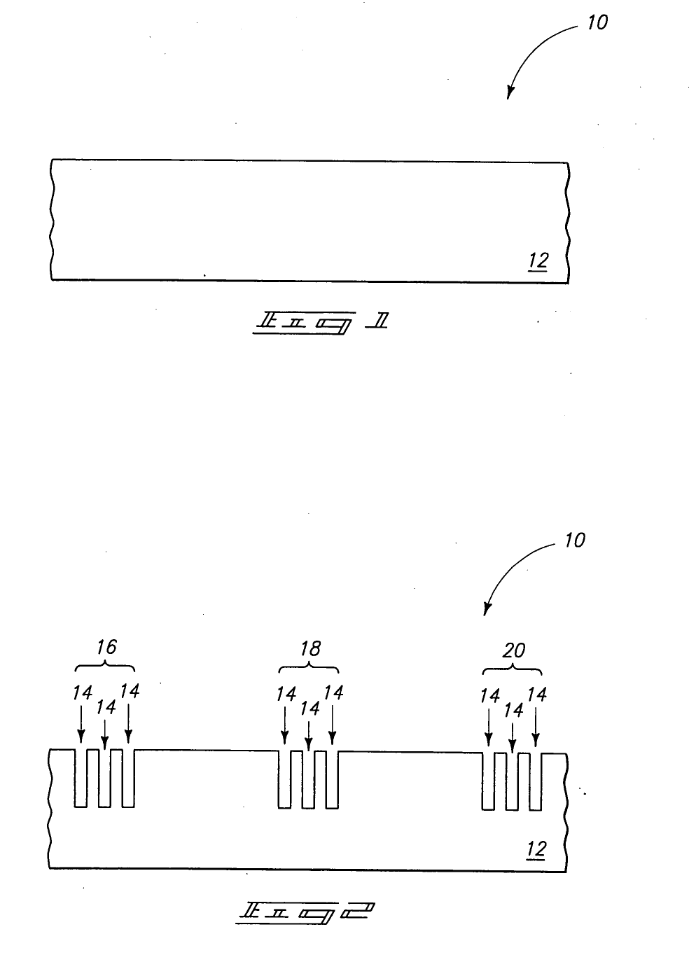

Exemplary aspects of the present invention are described with reference to FIGS. 1-12.

Referring to FIG. 1, a fragment 10 of a semiconductor wafer substrate 12 is illustrated at a preliminary processing stage of an exemplary aspect of the present invention. Substrate 12 can comprise, consist essentially of, or consist of any suitable semiconductor material. For instance, the substrate can comprise, consist essentially of, or consist of silicon, or doped silicon. In particular aspects, the semiconductor substrate 12 will comprise, consist essentially of, or consist of silicon doped to a total dopant concentration of less than or equal to about 10⁻¹⁹ atoms/cm³ with one or both of p-type and n-type dopant. As another example, the semiconductor substrate 12 can comprise, consist essentially of, or consist of germanium or silicon/germanium. As yet another example, the semiconductor substrate 12 can comprise, consist essentially of, or consist of one or more of gallium nitride, gallium arsenide and indium phosphate.

To aid in interpretation of the claims that follow, the terms “semiconductive substrate” and “semiconductor substrate” are defined to mean any construction comprising semiconductive material, including, but not limited to, bulk semiconductive materials such as a semiconductive wafer (either alone or in assemblies comprising other materials thereon), and semiconductive material layers (either alone or in assemblies comprising other materials). The term “substrate” refers to any supporting structure, including, but not limited to, the semiconductive substrates described above.

The semiconductor composition of substrate 12 can be considered to be a semiconductor material, and as discussed above, such material can, for example, comprise one or more of silicon, germanium, gallium nitride, gallium arsenide and indium phosphate.

Referring to FIG. 2, a plurality of openings 14 are formed to extend into the semiconductor material of semiconductor substrate 12. The openings are grouped amongst three sets 16, 18 and 20 in the shown aspect of the invention.

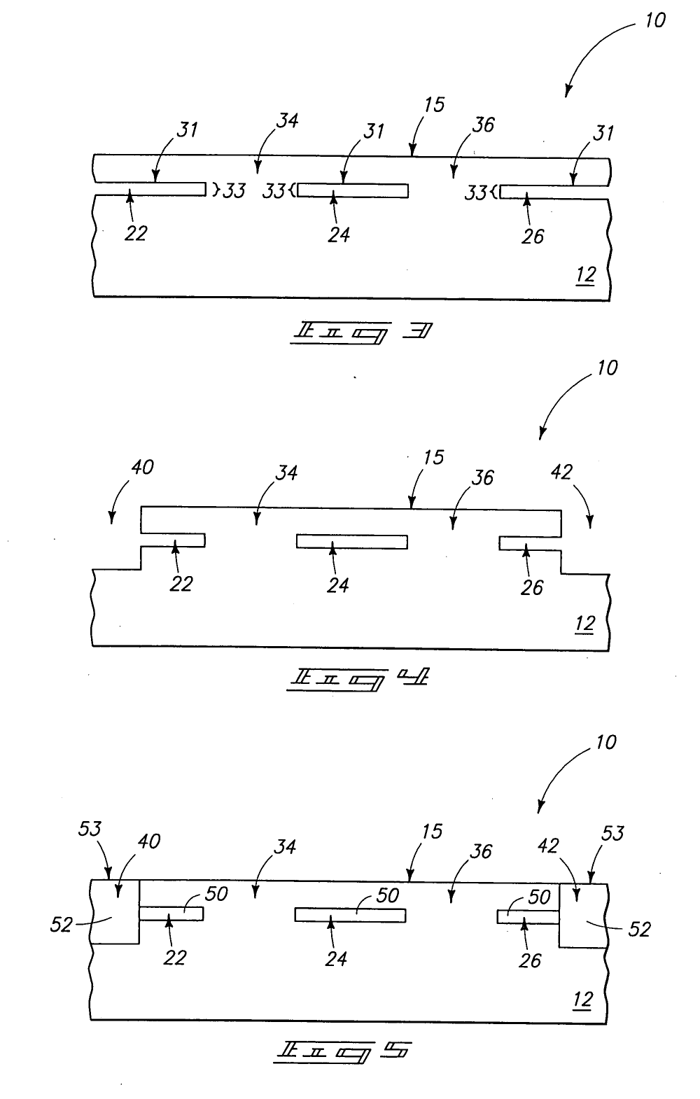

Referring to FIG. 3, semiconductor material of substrate 12 is annealed around the openings 14 (FIG. 2) to form cavities 22, 24 and 26 within the semiconductor material substrate 12. The openings 14 thus are utilized to define the size and locations of the cavities.

The annealing can be conducted in the presence of H₂, utilizing, for example, methodology of the type described in Sato et al., (“Fabrication of Silicon-on-Nothing Structure by Substrate Engineering Using the Empty-Space-in-Silicon Formation Technique”; Tsutomu Sato et al; Japanese Journal of Applied Physics; Vol. 43, No. 1, 2004; pp. 12-18).

The openings 14 of FIG. 2 can be provided to any appropriate depth, and in any appropriate configuration to form cavities of desired length and depth within the semiconductor material of substrate 12. In the shown aspect of the invention, the three sets 16, 18 and 20 of the openings of FIG. 2 have translated into three separate cavities 22, 24 and 26, respectively.

The fragment 10 of FIG. 3 has an uppermost surface 15, and the cavities have uppermost surfaces 31. in particular aspects, the uppermost surfaces of the cavities are from about 100 Å to about 1000 Å beneath the uppermost surface 15 of substrate 12. The cavities have thicknesses 33. Such thicknesses can be any suitable thicknesses, and in particular aspects the thicknesses will be from about 100 Å to about 500 Å.

The cavities 22, 24 and 26 are spaced from one another by intervening regions 34 and 36 of the semiconductor material.

Referring to FIG. 4, openings 40 and 42 are etched into the semiconductor material of substrate 12. Openings 40 and 42 expose cavities 22 and 26, respectively. Cavity 24 can be exposed with another opening which is outside of the shown plane of the cross-section of FIG. 4.

The formation of openings 40 and 42, as well as the above-discussed formation of openings 14, can be accomplished by providing a patterned masking material (not shown), or combination of materials, over substrate 12 to define the locations for the openings, and then subsequently removing the masking material. For instance, exemplary patterned masking materials can be photoresist, and/or stacks comprising silicon nitride over silicon dioxide.

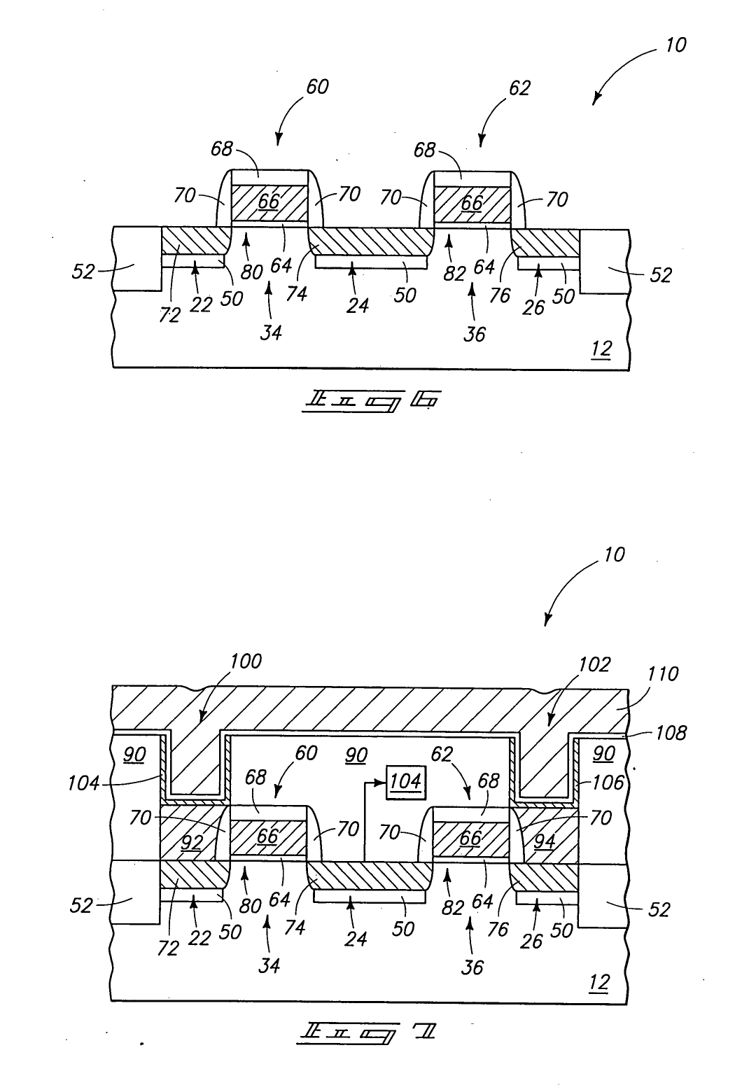

Referring to FIG. 5, cavities 22, 24 and 26 are substantially filled with material 50, and openings 40 and 42 are substantially filled with material 52. Materials 50 and 52 can be referred to as first and second compositions, respectively, and can be the same as one another or different. In particular aspects, material 50 will comprise an electrically insulative material, such as, for example, silicon dioxide, or one or more polymeric compositions. Exemplary insulative polymeric compositions include polysilazanes and other materials that are conventionally utilized as spin-on dielectric (SOD) materials. Additionally, or alternatively, material 50 can comprise one or more so-called high-k compositions, with high-k compositions being understood to be compositions having a dielectric constant greater than that of silicon dioxide; and with exemplary high-k compositions including tantalum pentoxide, aluminum oxide, and lead zirconate titanate. In some aspects, material 50 can consist essentially of, or consist of silicon dioxide, one or more high-k dielectric materials, or one or more polymeric compositions.

Although all of the shown cavities 22, 24 and 26 are indicated to be substantially filled with material 50, it is to be understood that the invention also encompasses aspects in which only some of the cavities are substantially filled with the material, and others of the cavities are left unfilled. It can be advantageous, however, for all of the cavities to be processed substantially the same as one another, and accordingly for all of the cavities to have the material 50 provided therein.

The substantially filled cavities 22, 24 and 26 can be considered to be segments of material 50 which are spaced from one another by the intervening regions 34 and 36 of the semiconductor material of substrate 12.

The electrically insulative material 52 provided within openings 40 and 42 can ultimately be incorporated into trenched isolation regions. Accordingly, in particular aspects the material 52 will comprise a material suitable for trenched isolation regions, with an exemplary material comprising, consisting essentially of, or consisting of silicon dioxide. In some aspects of the invention, materials 50 and 52 will both comprise electrically insulative materials, and in such aspects material 50 can be referred to as a first electrically insulative material, and material 52 can be referred to as a second electrically insulative material. The first electrically insulative material 50 directly contacts the second electrically insulative material 52 since the openings 40 and 42 were utilized to access the cavities during filling of the cavities with electrically insulative material 50, and were then subsequently filled with the electrically insulative material 52. If material 52 corresponds to trenched isolation regions, it can be considered that at least some of the segments of electrically insulative material 50 directly contact such trenched isolation regions, and in particular aspects all of the segments of first electrically insulative material will directly contact trenched isolation regions corresponding to second electrically insulative material 52.

In some aspects, the first electrically insulative material 50 and second electrically insulative material 52 comprise the same composition as one another, and in such aspects the first and second electrically insulative materials can be formed in a common processing step. For instance, if first and second electrically insulative materials 50 and 52 both comprise silicon dioxide, the first and second electrically insulative materials can be formed in a common silicon dioxide deposition step (with such common deposition step being understood to be a step in which vacuum to a process chamber is not broken from the time that deposition of electrically insulative material 50 is started until the time that deposition of electrically insulative material 52 has ended).

In some aspects at least some of material 52 will differ from material 50. In such aspects, at least some of material 52 can be formed in a different processing step from the step utilized to form material 50. For instance, if material 50 comprises silicon dioxide, there may be some silicon dioxide formed within the openings 40 and 42 during the deposition of material 50, but the majority of the material 52 formed within openings 40 and 42 can be an insulative material different than silicon dioxide, such as, for example, silicon nitride and/or various high-k materials. In such aspects, the first and second electrically insulative materials 50 and 52 can be considered to differ in composition from one another in that the entirety of material 50 is not compositionally the same as the entirety of the material 52.

As is clear from the discussion above, material 50 can comprise a single homogeneous composition, or can comprise a plurality of compositions; and similarly material 52 can comprise a single homogeneous composition, or can comprise a plurality of compositions.

Cavities 22, 24 and 26 are referred to as being “substantially filled” with material 50 to indicate that the material fills the majority of the volume of the cavities, which can include, but is not limited to, aspects in which the material 50 entirely fills the volume of the cavities. Similarly, material 52 is referred to as “substantially filling” openings 40 and 42 to indicate that the material 52 fills the majority of the volume of openings 40 and 42, and can, in some aspects entirely fill the volume of openings 40 and 42.

In the shown aspect of the invention, construction 10 has a planarized upper surface which extends across the surface 15 of substrate 12, as well as across uppermost surfaces 53 of the material 52 within openings 40 and 42. Such planarized upper surface can be formed by, for example, forming material 52 in sufficient quantity to overfill openings 40 and 42 and extend across surface 15 of substrate 12, and subsequently removing the overfill by, for example, chemical-mechanical polishing. Although the construction 10 is shown to have a planarized surface extending across the surface of substrate 12 and the surfaces of trenched isolation regions 52, it is to be understood that the invention encompasses other aspects (not shown) in which the trenched isolation regions have surfaces projecting either above or below the surface 15 of substrate 12 at the processing stage of FIG. 5, and at the processing stages 6-8 which follow FIG. 5.

The construction of FIG. 5 can be considered to be an SOI-type construction. Specifically, material 50 can correspond to an insulative material, and the segments 22, 24 and 26 of such insulative material can be considered to partially separate a bulk semiconductor material beneath the segments from a layer of semiconductor material above the segments. The layer of the semiconductor material above the segments connects with the bulk semiconductor material below the segments through the intervening regions 34 and 36 extending between the segments.

Referring to FIG. 6, transistors 60 and 62 are formed to be supported by semiconductor material of substrate 12, and specifically by the SOI-type construction of FIG. 5.

The transistors 60 and 62 comprise gate stacks containing gate dielectric 64, conductive gate material 66, and electrically insulative caps 68. The gate dielectric 64 can, for example, comprise, consist essentially of, or consist of silicon dioxide. The electrically conductive gate material 66 can, for example, comprise, consist essentially of, or consist of one or more of conductively-doped semiconductor material (such as conductively-doped silicon), metal (such as titanium or tungsten) and metal composition (such as metal silicide). The electrically insulative caps 68 can, for example, comprise, consist essentially of, or consist of one or more of silicon dioxide, silicon nitride and silicon oxynitride.

The transistors 60 and 62 comprise sidewall spacers 70 along sidewalls of the gate stacks. The sidewall spacers can, for example, correspond to anisotropically-etched electrically insulative material comprising one or more of silicon dioxide, silicon nitride and silicon oxynitride.

Transistor 60 comprises a pair of source/drain regions 72 and 74 extending within semiconductor material of substrate 12, and transistor device 62 comprises a pair of source/drain regions 74 and 76 extending within the semiconductor material. In the shown aspect of the invention, the source/drain region 74 is shared between transistor devices 60 and 62, as would be typical in some forms of tightly-packed memory circuitry. It is to be understood, however, that the invention also encompasses aspects in which the transistor devices do not share a source/drain region. Further, although the transistor devices are shown having gates with the same compositions as one another, it is to be understood that the invention also encompasses aspects in which one or more transistor devices have gate materials which differ from the materials of one or more other transistor devices.

Source/drain regions 72, 74 and 76 correspond to conductively-doped diffusion regions extending into semiconductor material of substrate 12. Such conductively-doped regions can comprise one or both of n-type dopant and p-type dopant. In particular aspects, the conductively-doped diffusion regions will be heavily-doped with n-type dopant so that transistors 60 and 62 correspond to n-type metal oxide semiconductor (NMOS) transistors. In such aspects, semiconductor material 12 can be lightly-background-doped with p-type dopant.

The transistors 60 and 62 comprise channel regions 80 and 82, respectively beneath the transistor gates. The channel regions can be doped with an appropriate threshold voltage (Vₜ) dopant.

In the aspect of the invention shown in FIG. 6, the source/drain regions 72, 74 and 76 are directly over segments 22, 24 and 26 of electrically insulative material 50, and channel regions 80 and 82 are associated with intervening regions 34 and 36 of semiconductor material 12 between the segments of electrically insulative material 50. In other words, the channel regions are not directly over segments of insulative material 50, or at least the majority of an individual channel region is not directly over a segment of the insulative material 50.

The amount of an individual source/drain region that is over a segment of insulative material 50 can vary according to desired applications and processing procedures. In some aspects an entirety of a source/drain region is directly over a segment of insulative material, and in other aspects only a portion of a source/drain region is directly over a segment of the insulative material. In particular aspects, a majority of a source/drain region is directly over a segment of insulative material 50, and in such aspects the source/drain region can be considered to be “primarily directly over” the segment of the insulative material. It can be desired to have enough of a source/drain region directly over a segment of insulative material 50 so that properties of the source/drain region are influenced by the segment of insulative material.

In the shown aspect of the invention, the transistor devices each have paired source/drain regions which are directly over pairs of segments of electrically insulative material 50, and the channel regions 80 and 82 are between the pairs of segments of insulative material 50 associated with the paired source/drain regions. It is to be understood, however, that the invention also encompasses aspects in which at least some segments of the material 50 are long enough to extend beneath the entire active region associated with a transistor (specifically, beneath both of the paired source/drain regions and beneath the channel region). Also, although all of the source/drain regions are shown directly over segments of insulative material 50, it is to be understood that the invention also encompasses aspects in which some source/drain regions are directly over segments of insulative material 50 and others are not.

Referring to FIG. 7, an electrically insulative material 90 is formed over transistors 60 and 62, insulative material 52, and semiconductor substrate 12. Electrically insulative material 90 can comprise any suitable composition or combination of compositions, and in particular aspects can comprise, consist essentially of, or consist of one or more of silicon dioxide, silicon nitride, and various doped silicon oxides, including, for example, borophosphosilicate glass (BPSG).

Conductive pedestals 92 and 94 are formed over source/drain regions 72 and 76 and electrically coupled with such source/drain regions. The electrically conductive pedestals 92 and 94 can comprise any suitable composition or combination of compositions, and in particular aspects can comprise one or more of conductively-doped semiconductor material (such as conductively-doped silicon), metal (such as tungsten), and metal compound (such as titanium silicide).

A pair of capacitor structures 100 and 102 are formed to be electrically coupled with conductive pedestals 92 and 94, respectively. The shown capacitor structures are container-type capacitors. The capacitors comprise conductive storage nodes 104 and 106, dielectric material 108, and a capacitor plate 110. The storage nodes 104 and 106 can comprise any suitable electrically conductive material or combination of materials, and in particular aspects can comprise one or more of conductively-doped semiconductor material, metal compound and metal. The dielectric material 108 can comprise any suitable composition or combination of compositions, and in particular aspects can comprise, consist essentially of, or consist of one or more of silicon dioxide, silicon nitride, and various high-k materials. The capacitor plate 110 can comprise any suitable electrically conductive composition or combination of compositions, and in particular aspects can comprise one or more of conductively-doped semiconductor material, metal compounds and metal.

The transistors and capacitors can be incorporated into integrated circuitry as memory devices, such as, for example, as DRAM devices associated with a memory array. The shared source/drain region 74 is shown electrically coupled with a bitline 104. Thus, the gates of transistors 60 and 62 can be formed along wordlines, the shared source/drain region 74 can be electrically coupled with a bitline, and the shown combination of transistor 60/capacitor 100, and transistor 62/capacitor 102 can correspond to DRAM unit cells which are part of a DRAM array.

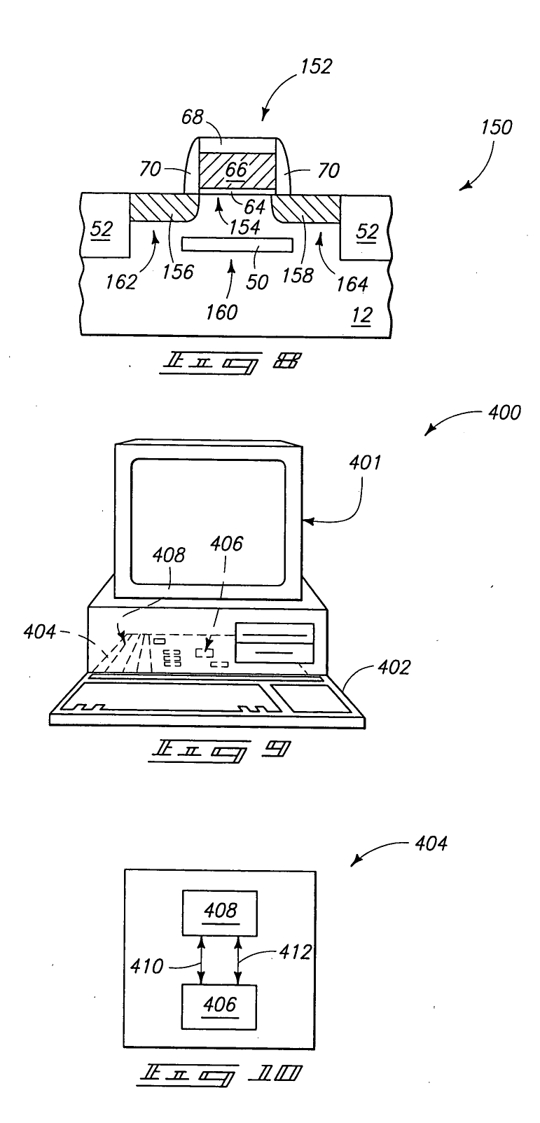

The aspect of FIG. 7 in which segments of insulative material 50 are beneath source/drain regions of transistors can be particularly advantageous for utilization in DRAM applications in that the isolation regions corresponding to segments 50 can block charge-transfer between a capacitor of a DRAM and the underlying bulk semiconductor material of substrate 12, and can also aid in improving refresh characteristics of the transistor devices. However, in logic applications it may be more advantageous to form the segments 50 of insulative material beneath a channel region of a transistor, rather than beneath source/drain regions of the transistor. FIG. 8 shows an exemplary construction 150 comprising a segment of electrically insulative material beneath a channel region of a transistor device. In referring to FIG. 8, similar numbering will be used as was utilized above in describing the embodiment of FIG. 7, where appropriate.

Construction 150 comprises a transistor 152 over a semiconductor substrate 12. The transistor comprises the gate dielectric 64, conductive gate material 66, insulative cap 68, and sidewall spacers 70 discussed previously relative to transistors 60 and 62. Further, transistor 152 comprises conductively-doped diffusion regions 156 and 158 corresponding to source/drain regions, and comprises a channel region 154 between the source/drain regions 156 and 158.

The construction 150 also comprises trenched isolation regions containing the insulative material 52, analogous to the trenched isolation regions containing insulative material 52 discussed previously.

A segment 160 of insulative material 50 is within substrate 12 and directly beneath channel region 154. Such segment can be in direct contact with an opening that is not visible in the cross-sectional view of FIG. 8, and which is either into or out of the plane of the cross-section of FIG. 8, with such opening being used to fill a cavity corresponding to segment 160 (such as, for example, a cavity analogous to the cavities of FIG. 4) with the insulative material 50.

Regions 162 and 164 of semiconductor material of substrate 12 are adjacent segment 160 of insulative material 150. The source/drain regions 156 and 158 are over the regions 162 and 164 of semiconductor material, and accordingly are not directly over the segment 160 comprising insulative material 50, or at least the majorities of the source/drain regions are not directly over such segment 160. In contrast, the majority, and in the shown aspect the entirety, of the channel region 154 is over segment 160 of insulative material 50. In aspects in which the majority of a channel region is directly over a segment of insulative material, the channel region can be referred to as being “primarily directly over” the segment.

The aspect of FIG. 8 in which a segment of insulative material is beneath a channel region and not beneath source/drain regions may be more likely to lead to a transistor devices having electrical properties very much like conventional SOI devices than does the aspect of FIGS. 6 and 7 in which the source/drain regions are directly over segments of the insulative material.

Applications of the type described with reference to FIGS. 1-8 can be utilized in numerous devices, including, for example, memory devices and processors, with applications extending to radiation-hard devices, such as, for example, devices utilized in military applications, in that the devices formed with methodology of FIGS. 1-8 may be particularly robust relative to environmental damage by virtue of, among other things, elimination of floating body effects associated with conventional SOI constructions.

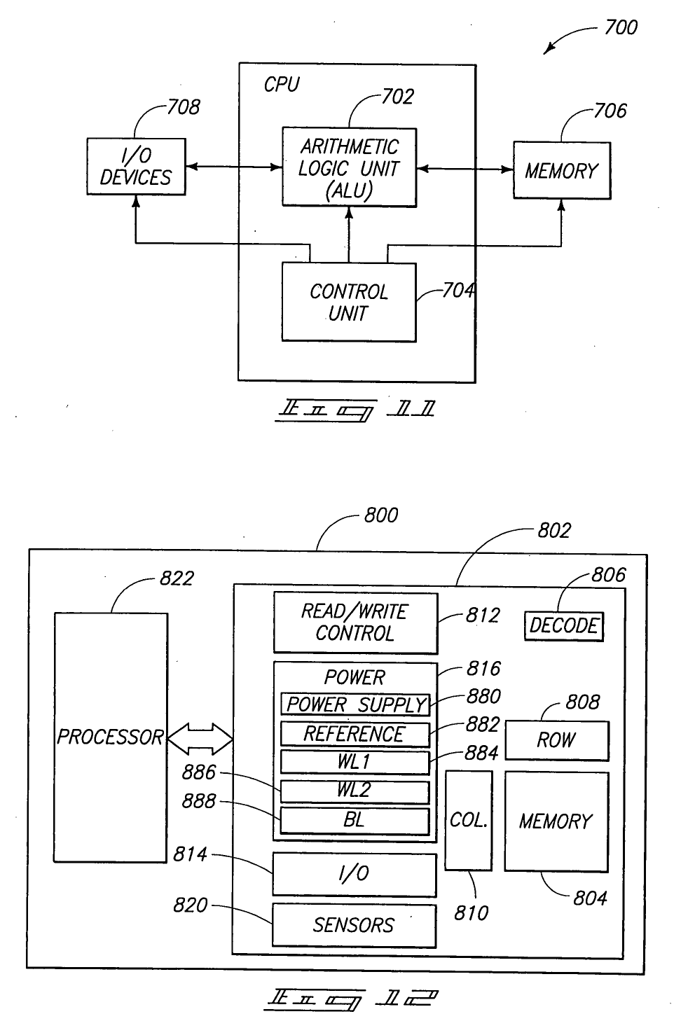

FIG. 9 illustrates generally, by way of example but not by way of limitation, an embodiment of a computer system 400 according to an aspect of the present invention. Computer system 400 includes a monitor 401 or other communication output device, a keyboard 402 or other communication input device, and a motherboard 404. Motherboard 404 can carry a microprocessor 406 or other data processing unit, and at least one memory device 408. Memory device 408 can comprise various aspects of the invention described above. Memory device 408 can comprise an array of memory cells, and such array can be coupled with addressing circuitry for accessing individual memory cells in the array. Further, the memory cell array can be coupled to a read circuit for reading data from the memory cells. The addressing and read circuitry can be utilized for conveying information between memory device 408 and processor 406. Such is illustrated in the block diagram of the motherboard 404 shown in FIG. 10. In such block diagram, the addressing circuitry is illustrated as 410 and the read circuitry is illustrated as 412. Various components of computer system 400, including processor 406, can comprise one or more of the memory constructions described previously in this disclosure.

Processor device 406 can correspond to a processor module, and associated memory utilized with the module can comprise teachings of the present invention.

Memory device 408 can correspond to a memory module. For example, single in-line memory modules (SIMMs) and dual in-line memory modules (DIMMs) may be used in the implementation which utilize the teachings of the present invention. The memory device can be incorporated into any of a variety of designs which provide different methods of reading from and writing to memory cells of the device. One such method is the page mode operation. Page mode operations in a DRAM are defined by the method of accessing a row of a memory cell arrays and randomly accessing different columns of the array. Data stored at the row and column intersection can be read and output while that column is accessed.

An alternate type of device is the extended data output (EDO) memory which allows data stored at a memory array address to be available as output after the addressed column has been closed. This memory can increase some communication speeds by allowing shorter access signals without reducing the time in which memory output data is available on a memory bus. Other alternative types of devices include SDRAM, DDR SDRAM, SLDRAM, VRAM and Direct RDRAM, as well as others such as SRAM or Flash memories.

Memory device 408 can comprise memory formed in accordance with one or more aspects of the present invention.

FIG. 11 illustrates a simplified block diagram of a high-level organization of various embodiments of an exemplary electronic system 700 of the present invention. System 700 can correspond to, for example, a computer system, a process control system, or any other system that employs a processor and associated memory. Electronic system 7.00 has functional elements, including a processor or arithmetic/logic unit (ALU) 702, a control unit 704, a memory device unit 706 and an input/output (I/O) device 708. Generally, electronic system 700 will have a native set of instructions that specify operations to be performed on data by the processor 702 and other interactions between the processor 702, the memory device unit 706 and the I/O devices 708. The control unit 704 coordinates all operations of the processor 702, the memory device 706 and the I/O devices 708 by continuously cycling through a set of operations that cause instructions to be fetched from the memory device 706 and executed. In various embodiments, the memory device 706 includes, but is not limited to, random access memory (RAM) devices, read-only memory (ROM) devices, and peripheral devices such as a floppy disk drive and a compact disk CD-ROM drive. One of ordinary skill in the art will understand, upon reading and comprehending this disclosure, that any of the illustrated electrical components are capable of being fabricated to include memory constructions in accordance with various aspects of the present invention.

FIG. 12 is a simplified block diagram of a high-level organization of various embodiments of an exemplary electronic system 800. The system 800 includes a memory device 802 that has an array of memory cells 804, address decoder 806, row access circuitry 808, column access circuitry 810, read/write control circuitry 812 for controlling operations, and input/output circuitry 814. The memory device 802 further includes power circuitry 816, and sensors 820, such as current sensors for determining whether a memory cell is in a low-threshold conducting state or in a high-threshold non-conducting state. The illustrated power circuitry 816 includes power supply circuitry 880, circuitry 882 for providing a reference voltage, circuitry 884 for providing the first wordline with pulses, circuitry 886 for providing the second wordline with pulses, and circuitry 888 for providing the bitline with pulses. The system 800 also includes a processor 822, or memory controller for memory accessing.

The memory device 802 receives control signals from the processor 822 over wiring or metallization lines. The memory device 802 is used to store data which is accessed via I/O lines. It will be appreciated by those skilled in the art that additional circuitry and control signals can be provided, and that the memory device 802 has been simplified to help focus on the invention. At least one of the processor 822 or memory device 802 can include a memory construction of the type described previously in this disclosure.

The various illustrated systems of this disclosure are intended to provide a general understanding of various applications for the circuitry and structures of the present invention, and are not intended to serve as a complete description of all the elements and features of an electronic system using memory cells in accordance with aspects of the present invention. One of the ordinary skill in the art will understand that the various electronic systems can be fabricated in single-package processing units, or even on a single semiconductor chip, in order to reduce the communication time between the processor and the memory device(s).

Applications for memory cells can include electronic systems for use in memory modules, device drivers, power modules, communication modems, processor modules, and application-specific modules, and may include multilayer, multichip modules. Such circuitry can further be a subcomponent of a variety of electronic systems, such as a clock, a television, a cell phone, a personal computer, an automobile, an industrial control system, an aircraft, and others.

In compliance with the statute, the invention has been described in language more or less specific as to structural and methodical features. It is to be understood, however, that the invention is not limited to the specific features shown and described, since the means herein disclosed comprise preferred forms of putting the invention into effect. The invention is, therefore, claimed in any of its forms or modifications within the proper scope of the appended claims appropriately interpreted in accordance with the doctrine of equivalents.

1-26. (canceled)

27. A method of forming integrated circuitry, comprising:
providing a semiconductor material;
forming openings extending into the semiconductor material and annealing the substrate around the openings to form cavities within the semiconductor material;
substantially filling the cavities with an electrically insulative material to form segments of the electrically insulative material, the segments being spaced from one another by intervening regions of the semiconductor material;
forming a transistor supported by the semiconductor material; the transistor comprising a transistor gate over the semiconductor material, and comprising a pair of source/drain regions proximate the gate; the transistor further comprising a channel region beneath the gate and between the source/drain regions; and
wherein the source/drain regions are primarily directly over one or more of the segments of the electrically insulative material.

28. The method of claim 27 wherein the source/drain regions are primarily directly over a pair of the segments of the electrically insulative material, and wherein the channel region is associated with an intervening region of the semiconductor material between the pair of the segments of the electrically insulative material.

29. The method of claim 27 wherein the semiconductor substrate comprises silicon.

30. The method of claim 27 wherein the semiconductor substrate comprises germanium.

31. The method of claim 27 wherein the electrically insulative material has a dielectric constant greater than that of silicon dioxide.

32. The method of claim 27 wherein the electrically insulative material consists essentially of silicon dioxide.

33. The method of claim 27 wherein the electrically insulative material consists essentially of one or more polymeric compositions.

34. A method of forming a dynamic random access memory cell, comprising:
providing a semiconductor material;
forming openings extending into the semiconductor material and annealing the substrate around the openings to form cavities within the semiconductor material;
substantially filling the cavities with an electrically insulative material to form segments of the electrically insulative material, the segments being spaced from one another by intervening regions of the semiconductor material;
forming a transistor supported by the semiconductor material; the transistor comprising a transistor gate over the semiconductor material, and comprising a pair of source/drain regions proximate the gate; the transistor further comprising a channel region beneath the gate and between the source/drain regions; the source/drain regions being primarily directly over a pair of the segments of the electrically insulative material, and the channel region being associated with an intervening region of the semiconductor material between the pair of the segments of the electrically insulative material; and
forming a capacitor electrically coupled with one of the source/drain regions.

35. The method of claim 34 wherein the semiconductor substrate comprises silicon.

36. The method of claim 34 wherein the semiconductor substrate comprises germanium.

37. The method of claim 34 wherein the electrically insulative material has a dielectric constant greater than that of silicon dioxide.

38. The method of claim 34 wherein the electrically insulative material consists essentially of silicon dioxide.

39. The method of claim 34 wherein the electrically insulative material consists essentially of one or more polymeric compositions.

40. The method of claim 34 wherein the electrically insulative material is a first electrically insulative material, and further comprising:
etching into the substrate to form trenches and expose the cavities;
after forming the trenches, substantially filling the cavities with the first electrically insulative material; and
forming a second electrically insulative material within the trenches.

41. The method of claim 40 wherein the first and second electrically insulative materials are the same in composition as one another.

42. The method of claim 41 wherein the first and second electrically insulative materials comprise silicon dioxide.

43. The method of claim 41 wherein the trenches are substantially filled with the second electrically insulative material.

44. The method of claim 43 wherein the substantially filling the trenches with the second electrically insulative materials occurs in a common processing step with the substantially filling the cavities with the first electrically insulative material.

45. The method of claim 40 wherein the first and second electrically insulative materials are different in composition from one another.

46. The method of claim 45 wherein the first electrically insulative material comprises silicon dioxide and the second electrically insulative material comprises a composition with a higher dielectric constant than silicon dioxide.

47. The method of claim 45 wherein the trenches are substantially filled with the second electrically insulative material.

48-106. (canceled)
